(19) United States
(12) Patent Application Publication
(10) Pub. No.: US 2019/0156972 A1
(43) Pub. Date: May 23, 2019

(54) ELECTRONIC FUNCTIONAL MEMBER, KNITTED PRODUCT USING THE SAME, AND METHOD FOR MANUFACTURING ELECTRONIC FUNCTIONAL MEMBER

(71) Applicant: Murata Manufacturing Co., Ltd., Nagaokakyo-shi (JP)

(72) Inventors: Masahiko KONDO, Nagaokakyo-shi (JP); Osamu ONISHI, Kitakatsuragi-gun (JP); Kanako ANDO, Kitakatsuragi-gun (JP)

(21) Appl. No.: 16/239,970

(22) Filed: Jan. 4, 2019

Related U.S. Application Data
(63) Continuation of application No. PCT/JP2017/022411, filed on Jun. 16, 2017.

(30) Foreign Application Priority Data
Aug. 4, 2016 (JP) 2016-153315
Apr. 19, 2017 (JP) 2017-083140

(51) Int. Cl. H01B 7/18; D04B 1/22; H01B 7/282; H05K 7/02; H01B 13/26; G01D 11/24

(52) U.S. Cl. CPC H01B 7/183; D04B 1/225; H01B 7/2825; H01B 7/1855; D10B 2401/18; H01B 7/1875; H01B 13/26; G01D 11/245; H05K 7/02

(57) ABSTRACT

An electronic functional member includes a core wire assembly including at least two metal wires, an insulating layer covering the at least two metal wires so as to expose a portion of the at least two metal wires, and an electronic functional element electrically conductive to each of the at least two metal wires, and a sheath including a knitted fabric covering the core wire assembly.

### CROSS REFERENCE TO RELATED APPLICATIONS

This application claims the benefit of priority to Japanese Patent Application No. 2016-153315 filed on Aug. 4, 2016 and Japanese Patent Application No. 2017-083140 filed on Apr. 19, 2017, and is a Continuation Application of PCT Application No. PCT/JP2017/022411 filed on Jun. 16, 2017. The entire contents of each application are hereby incorporated herein by reference.

### BACKGROUND OF THE INVENTION

### 1. Field of the Invention

The present invention relates to an electronic functional member, a knitted product using the same, and a method for manufacturing an electronic functional member.

### 2. Description of the Related Art

Conventionally, characteristics such as a heat retention property and an antibacterial property have been widely applied to synthetic fibers such as clothing articles by coating or impregnating surfaces of the synthetic fibers with a functional material. On the other hand, in recent years, the application of electric and electronic functions to yarns or fabrics by carrying electronic components on the yarns or the fabrics has been studied.

For example, Japanese Patent Application Laid-Open No. 2013-189718 discloses a composite yarn and a fabric including the composite yarn. In the composite yarn, a support having an electronic component attached thereto is wound and fixed on the surface of a yarn on which a conductive pattern is formed, and a holding yarn is wound around the yarn to cover at least a portion of the electronic component.

However, the composite yarn of Japanese Patent Application Laid-Open No. 2013-189718 has a problem that the holding yarn itself is not flexible, which is apt to cause the composite yarn to be broken if stress is locally applied to an electronic component or a wiring. When a bending or tensile force is applied to the fabric including the composite yarn, the force is apt to be locally applied to the composite yarn, which is disadvantageously apt to cause the disconnection and breakage of the component.

### SUMMARY OF THE INVENTION

Preferred embodiments of the present invention provide yarn electronic functional members having electric and electronic functions and excellent flexibility and durability, knitted products using the same, and methods for manufacturing electronic functional members.

An electronic functional member according to a first aspect of a preferred embodiment of the present invention includes a core wire assembly including at least two metal wires, an insulating layer covering the at least two metal wires so as to expose a portion of the at least two metal wires, and an electronic functional element electrically conductive to each of the at least two metal wires; and a sheath including a knitted fabric covering the core wire assembly.

The first aspect of a preferred embodiment of the present invention can provide an electronic functional member that has electric and electronic functions, is resistant to bending and impact, and is capable of being knitted.

In a second aspect of a preferred embodiment of the present invention, the knitted fabric at least partially includes a thermoplastic synthetic resin.

According to the second aspect of a preferred embodiment of the present invention, the knitted fabric is easily melted and deformed by heat to increase the coverage of the core wire assembly.

In a third aspect of a preferred embodiment of the present invention, the core wire assembly is hermetically sealed to an outside in a region where the core wire assembly is covered with the knitted fabric.

According to the third aspect of a preferred embodiment of the present invention, the water resistance of the sheath is able to be improved.

In a fourth aspect of a preferred embodiment of the present invention, in the first aspect, the sheath includes a first cover located on a side of the core wire assembly including the knitted fabric, and a second cover covering at least a portion of the first cover and pressing the first cover toward the core wire assembly.

According to the fourth aspect of a preferred embodiment of the present invention, the first cover is able to be further brought into close contact with the core wire assembly.

In a fifth aspect of a preferred embodiment of the present invention, the second cover includes an elongated member helically wound around the first cover.

According to the fifth aspect of a preferred embodiment of the present invention, the first cover is able to be brought into close contact with the core wire assembly without damaging the core wire assembly.

In a sixth aspect of a preferred embodiment of the present invention, the electronic functional element may be a chip component, an electronic functional substance-containing film, a battery, an input element, a display element, a sensor, an antenna, and a composite element and integrated circuit thereof.

According to the sixth aspect of a preferred embodiment of the present invention, a size and thickness of the electronic functional member to be mounted is able to be further reduced so that the electronic functional member can be thinner.

In a seventh aspect of a preferred embodiment of the present invention, the core wire assembly includes a plurality of electronic functional elements, and the plurality of electronic functional elements are interconnected by the metal wires to define a circuit.

According to the seventh aspect of a preferred embodiment of the present invention, a use of the circuit in place of a component such as a chip makes it possible to further downsize the electronic functional member.

According to an eighth aspect of a preferred embodiment of the present invention, the circuit includes a sensor as the electronic functional element.

According to an eighth aspect of a preferred embodiment of the present invention, the electronic functional member is usable as a measurement tool.

In a ninth aspect of a preferred embodiment of the present invention, the circuit further includes a controller that controls operation of the sensor, a communicator that outputs information from the sensor to the outside, and a power supply that supplies electric power to the sensor, the controller, and the communicator, as the electronic functional element.

According to the ninth aspect of a preferred embodiment of the present invention, the electronic functional member is able to be further downsized as a measurement tool.

In a tenth aspect of a preferred embodiment of the present invention, a knitted product is obtained by knitting the electronic functional member according to any one of the first to ninth aspects of preferred embodiments of the present invention used as at least a portion of the knitted product.

The tenth aspect of a preferred embodiment of the present invention provides a knitted product that has electric and electronic functions and is resistant to bending or impact.

In an eleventh aspect of a preferred embodiment of the present invention, the knitted product further includes a power supply electrically connected to the electronic functional element via the at least two metal wires.

According to the eleventh aspect of a preferred embodiment of the present invention, the need for an external power supply is eliminated.

In a twelfth aspect of a preferred embodiment of the present invention, the knitted product is obtained by knitting the electronic functional member used as at least a portion of the knitted product, the electronic functional member including a circuit in which a sensor, a controller that controls operation of the sensor, a communicator that outputs information from the sensor to an outside, and a power supply that supplies electric power to the sensor, the controller, and the communicator are interconnected.

According to the twelfth aspect of a preferred embodiment of the present invention, the shape of the knitted fabric obtained by knitting the electronic functional member including the circuit including the sensor used as at least a portion of the knitted fabric is not limited to the shape of an object to be measured, and the knitted fabric is able to be attached to the object to be measured, such that the knitted fabric can be used as a new measurement tool.

In a thirteenth aspect of a preferred embodiment of the present invention, a method for manufacturing an electronic functional member includes forming a core wire assembly including at least two metal wires, an insulating layer covering the at least two metal wires so as to expose a portion of the at least two metal wires, and an electronic functional element electrically conductive to each of the at least two metal wires; and forming a sheath covering the core wire assembly, wherein the forming the sheath includes at least knitting a knit fabric by weft knitting around the core wire assembly to cover the core wire assembly.

According to the thirteenth aspect of a preferred embodiment of the present invention, an electronic functional member that has electric and electronic functions and is resistant to bending and impact is manufactured.

In a fourteenth aspect of a preferred embodiment of the present invention, in the twelfth aspect, the step of forming the sheath includes helically winding an elongated member around the knitted fabric.

According to the fourteenth aspect of a preferred embodiment of the present invention, the first cover is able to be brought into closer contact with the core wire assembly.

Preferred embodiments of the present invention provide yarn electronic functional members having excellent flexibility and durability and a knitted fabric using the same.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a partially broken plan view of an electronic functional member according to a preferred embodiment 1 of the present invention.

FIG. 2 is a schematic longitudinal sectional view of the electronic functional member according to the preferred embodiment 1 of the present invention.

FIG. 3 is a developed view of a knitted fabric used for the electronic functional member according to the preferred embodiment 1 of the present invention.

FIG. 4 is a partially broken plan view of an electronic functional member according to a preferred embodiment 2 of the present invention.

FIG. 5 is a schematic longitudinal sectional view of the electronic functional member according to the preferred embodiment 2 of the present invention.

FIG. 6 is a partially broken plan view of an electronic functional member according to a preferred embodiment 3 of the present invention.

FIG. 7 is a schematic longitudinal sectional view of the electronic functional member according to the preferred embodiment 3 of the present invention.

FIG. 8 is a partially broken plan view of an electronic functional member according to a preferred embodiment 4 of the present invention.

FIG. 9 is a schematic longitudinal sectional view of the electronic functional member according to the preferred embodiment 4 of the present invention.

FIG. 10 is a schematic diagram showing an example of the structure of an electronic functional member of the present invention.

FIG. 11 is a block diagram showing an example of a built-in circuit of an electronic functional member according to a preferred embodiment 5 of the present invention.

### DETAILED DESCRIPTION OF THE PREFERRED EMBODIMENTS

Preferred embodiments will be described in detail below with reference to the drawings as appropriate.

### Preferred Embodiment 1

An electronic functional member according to the present preferred embodiment includes a core wire assembly including at least two metal wires, an insulating layer covering the at least two metal wires so as to expose a portion of the at least two metal wires, and an electronic functional element electrically conductive to each of the at least two metal wires, and a sheath including a knitted fabric covering the core wire assembly.

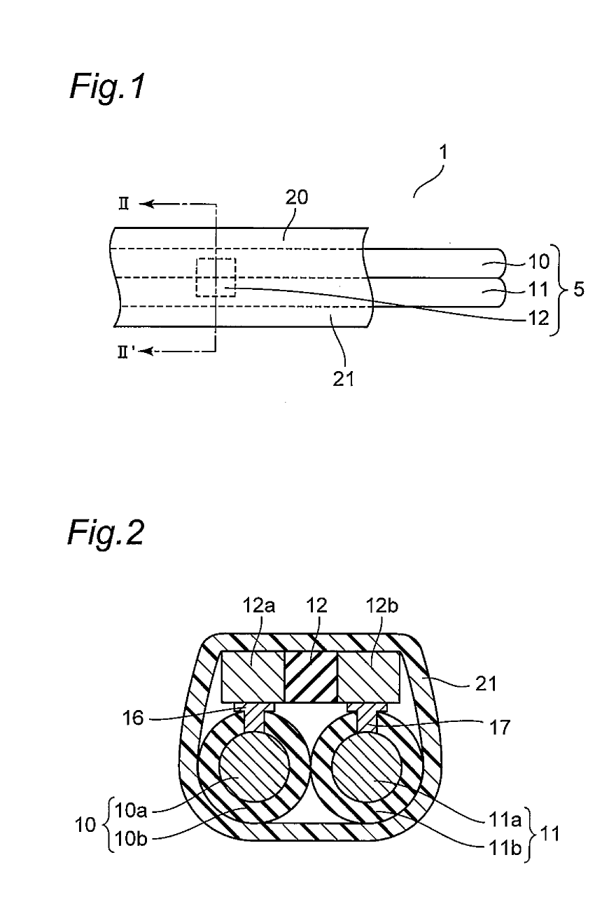

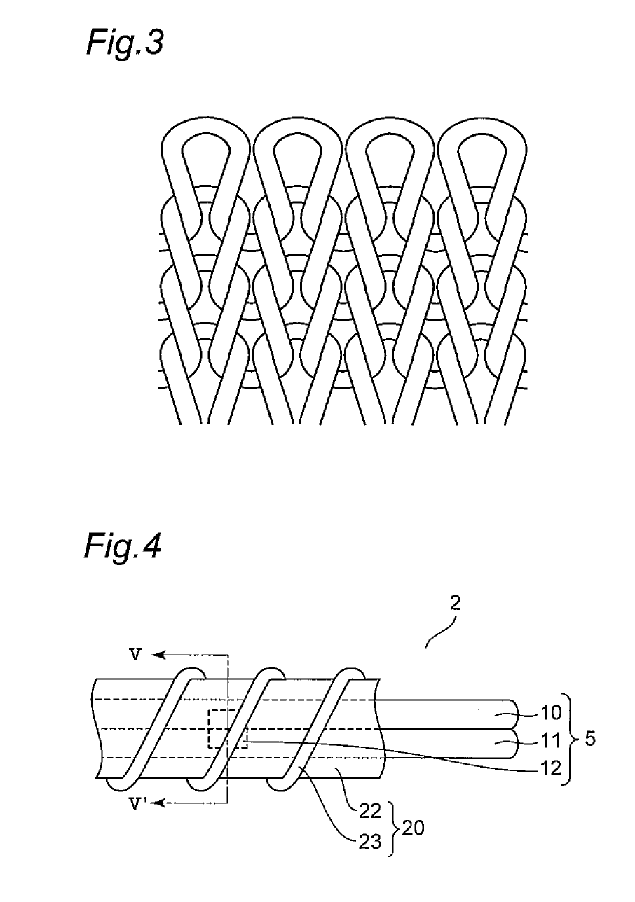

FIG. 1 is a partially broken plan view of an electronic functional member according to the present preferred embodiment, and FIG. 2 is a longitudinal sectional view taken along line II-II′ of FIG. 1. An electronic functional member 1 includes a core wire assembly 5 and a sheath 20 covering the core wire assembly 5. The core wire assembly 5 includes a first insulating coating metal wire 10 and a second insulating coating metal wire 11 extending in the longitudinal direction of the core wire assembly 5, and an electronic functional element 12 electrically conductive to each of the first insulating coating metal wire 10 and the second insulating coating metal wire 11. For the sheath 20, a knitted fabric 21 is preferably used. A chip component is preferably used for the electronic functional element 12.

As shown in FIG. 2, the first insulating coating metal wire 10 includes a metal wire 10a covered with an insulating layer 10b, and the second insulating coating metal wire 11 includes a metal wire 11a covered with an insulating layer 11b. A portion of the insulating layer 10b is removed to form a joint 16 so as to be in contact with the exposed metal wire 10a. A portion of the insulating layer 11b is removed to form a joint 17 so as to be in contact with the exposed metal wire 11a. The electronic functional element 12 preferably has a rectangular or substantially rectangular shape, and includes a pair of external electrodes 12a and 12b that are electronic functional elements provided at both end parts. By connecting the external electrode 12a to the joint 16 and connecting the external electrode 12b to the joint 17, the electronic functional element 12 is electrically connected to the metal wire 10a and the metal wire 11a. In this manner, the electronic functional element 12 and the metal wires 10a and 11a that are electrically connected to each other are covered with the knitted fabric 21. The joints 16 and 17 may be a structure different from the joint material by plating or the like, but when the insulating layers 10b and 11b are thin, the joints 16 and 17 may be defined by a joint material such as a solder or a conductive adhesive.

A copper wire or a nickel wire can be used for the metal wire of the core wire assembly. Preferably, a copper wire is used for the metal wire. The diameter of the metal wire is not particularly limited as long as the metal wire can be knitted into a knitted fabric, but the diameter preferably is about 1 μm or more and about 1 mm or less, and preferably about 1 μm or more and about 0.5 mm or less, for example. The insulating layer prevents the metal wires from being brought into direct contact with each other. As the insulating layer, a polyurethane resin, an acrylic resin, or an elongated insulating sheet or tape can be used. In the present aspect, the insulating layer causes a portion of the metal wire to be exposed in order to ensure electric conduction with the electronic functional element. Here, a portion of the metal wire may be other than the entire surface of the metal wire, and its area is not particularly limited.

The electronic functional element has a function of an active element such as a transistor, a diode, or a Peltier element, or a passive element such as a resistor, a capacitor, an inductor, or a thermistor. The electronic functional element capable of being used may be a chip component, an electronic functional substance-containing film, a battery, an input element, a display element, a sensor, an antenna, and a composite element and integrated circuit thereof.

The passive element may be a chip component, or an electronic functional substance-containing film such as a thick film resistor, a thin film resistor, a thin film capacitor, or a thin film inductor. The passive element may be an organic material, a composite material, or a paste material that contains an electronic functional substance. The electronic functional substance-containing film can be formed by applying a solution containing an element raw material, for example, a dielectric raw material, to the surfaces of a plurality of metal wires using a known thick film printing method such as spin coating or screen printing, and heating the solution. An electronic functional substance-containing film patterned by a thin film process can also be used. In that case, for example, a lift-off method, vapor deposition, sputtering or the like can be used. In the lift-off method, a resist is applied to each of the surfaces of a plurality of metal wires. Thereafter, the resist is patterned by lithography, and a solution containing an element raw material is then applied. Thereafter, the resist is peeled off, to allow only an intended thin film pattern to be left. Specific examples of the electronic functional element include an NTC thermistor, a PTC thermistor, and a Peltier element. The use of these elements for a clothing material including the electronic functional member makes it possible to measure the temperature of the clothing material, for example, when using the NTC thermistor. The use of the PTC thermistor makes it possible to warm the clothing material. The use of the Peltier element makes it possible to cool the clothing material.

The electronic functional element includes a plurality of terminals to transmit and receive signals to and from an external device. Specific examples of the terminals include an external electrode, a terminal, and an electrode pad. For example, when the two terminals are included, one of the terminals can be connected to one metal wire, and the other terminal can be connected to the other metal wire.

The sheath includes a knitted fabric covering the core wire assembly, and can include one or more covers laminated on the outer periphery of the core wire assembly. The knitted fabric can be used for any cover, and is preferably used for a first cover. The first cover is located on the side of the core wire assembly and at least a portion of the first cover is brought into contact with the core wire assembly. In the present preferred embodiment, an example is shown, in which the sheath includes only the first cover including the knitted fabric.

FIG. 3 shows a developed view of the knitted fabric 21. The knitted fabric 21 may define a tubular knitted fabric covering the core wire assembly 5 by subjecting a knitting yarn to weft knitting. The weft knitting is able to provide finer stitches than that of warp knitting, which is preferable. The weft knitting provides knitted stitches so that the core wire assembly in a longitudinal direction is wound by a knitting yarn, such that the core wire assembly is able to be relatively strongly tightened by the knitting yarn of the sheath. This allows the sheath to be brought into close contact with the core wire assembly.

As the knitting yarn, a yarn at least partially including a thermoplastic resin is able to be used. Examples of the thermoplastic resin include a polyurethane resin, a polyethylene resin, a polyester resin, a polyamide resin, and a polypropylene resin. Preferably, a thermoplastic synthetic fiber yarn made of a thermoplastic resin such as a polyethylene resin, a polyester resin, a polyamide resin, or a polypropylene resin can be used. The thickness of the knitting yarn is preferably about 33 dtex or more and about 250 dtex or less, for example. When the thickness is smaller than about 33 dtex, the core wire assembly is not sufficiently covered with the knitted fabric. When the thickness is more than about 250 dtex, the knitting yarn is too thick, which causes difficult knitting provided by a knitting machine. It is also possible to use a plurality of thermoplastic synthetic fiber yarns made of thermoplastic resins having different melting points, or a composite fiber made of a thermoplastic synthetic fiber yarn and a yarn having no thermoplasticity, or the like.

The number of stitches of the same course in the knitted fabric is preferably 2 or more and 6 or less, for example. The diameter of the tubular knitted fabric is able to be reduced such that the adhesion of the knitted fabric to the core wire assembly is able to be further improved.

The number of stitches per 1 cm of the natural length of the same wale in the knitted fabric is preferably 6 or more and 14 or less, for example. Here, the natural length means a length in a state where tension or the like is not present, that is, a state where the knitted fabric is naturally placed on a table as it is. When the number of stitches per 1 cm of the natural length of the same wale in the knitted fabric is 6 or more, the coverage of the knitted fabric to the core wire assembly is able to be increased. When the number of stitches per 1 cm of the natural length of the same wale in the knitted fabric is 14 or less, the occurrence of defects caused by the confined stitches (tuck flaws) of the knitted fabric stitches caused by the excessively fine stitches is able to be reduced or prevented.

When a yarn containing a thermoplastic resin is used for at least a portion of the knitted yarn, the electronic functional member is able to be heated while being pressurized as necessary after knitting. By heating and melting the thermoplastic resin contained in the knitted fabric, the coverage and adhesion of the solidified knitted fabric to the core wire assembly are improved after cooling, such that the electronic functional member and the metal wire are protected from washing or moisture derived from sweat. By heating while pressurizing, the adhesion between the core wire assembly and the sheath is able to be further improved. When the composite fiber including the plurality of thermoplastic synthetic fiber yarns made of thermoplastic resins having different melting points is used for the knitting yarn, the composite fiber is heated to a temperature higher than the melting point of the thermoplastic resin having a low melting point and lower than the melting point of the thermoplastic resin having a high melting point, such that the thermoplastic resin having a high melting point keeps the state of the knitted fabric. Only the thermoplastic resin having a low melting point is melted, such that the durability is able to be improved.

The electronic functional member according to the present preferred embodiment can be manufactured, for example, by using the following method. That is, a method for manufacturing an electronic functional member according to the present preferred embodiment, the method includes forming a core wire assembly including at least two metal wires, an insulating layer covering the at least two metal wires so as to expose a portion of the at least two metal wires, and an electronic functional element electrically conductive to each of the at least two metal wires, and forming a sheath covering the core wire assembly, wherein the forming the sheath includes at least knitting a knit fabric by weft knitting around the core wire assembly to cover the core wire assembly.

The forming the core wire assembly may further include forming a conductive pattern on the plurality of metal wires, and mounting at least one electronic functional element on the plurality of metal wires. For example, when two metal wires are used, as shown in FIG. 2, a portion of an insulating layer on the surface of each of the metal wires is removed to expose the surface of the metal wire, thus forming a joint providing a conductive pattern. The number of the conductive patterns can be selected in accordance with the number of input/output terminals of the electronic functional elements and the number of the electronic functional elements. Various shapes such as a linear shape, a rectangular shape, a circular shape, and a dot shape can be used for the shape of the conductive pattern. When an electronic functional element is mounted on a plurality of metal wires, from the viewpoints of stretchability and durability, the electronic functional element is preferably mounted in a direction perpendicular or substantially perpendicular to the longitudinal direction of the plurality of metal wires on the plurality of metal wires parallel or substantially parallel to each other. When a plurality of electronic functional elements are mounted in the longitudinal direction of a metal wire, a plurality of conductive patterns can be formed at predetermined intervals along the longitudinal direction of the metal wire. The conductive pattern can be formed by using a printing method using a conductive paste or an electroplating method.

In the step of covering the core wire assembly, a tubular knitted fabric covering the core wire assembly can be formed by subjecting a knitting yarn to weft knitting using a circular knitting machine. As the circular knitting machine, for example, a known circular knitting machine as described in Japanese Utility Model Laid-Open No. 60-193993 can be used.

The electronic functional member according to the present preferred embodiment is supplied to a knitting machine and knitted as a normal yarn so that a knitted fabric can be manufactured. The electronic functional member may be combined with an ordinary natural fiber yarn, a semisynthetic fiber yarn, a synthetic fiber yarn or the like, and supplied to the knitting machine, or the electronic functional member may be supplied alone to the knitting machine. Examples of methods for combining an electronic functional member with an ordinary synthetic fiber yarn include a method for supplying and knitting an electronic functional member and an ordinary synthetic fiber yarn from yarn paths of different face yarns, and a method for supplying, aligning, and knitting an electronic functional member and an ordinary synthetic fiber yarn from a yarn path of the same face yarn. The knitted fabric can be knitted by flat knitting, rib knitting, interlock knitting, pearl knitting and the like. An electronic functional member and an ordinary synthetic fiber yarn can be respectively supplied from a yarn path of a face yarn and a yarn path of a back yarn to use plating knitting. From an economic viewpoint, an electronic functional member can be interwoven only in a specific necessary portion with intarsia knitting (interlock knitting).

The knitted fabric can include at least one power supply electrically connected to the electronic functional element. The electrical connection between the electronic functional element and the power supply can be provided by the metal wire of the core wire assembly, which makes it unnecessary to newly provide a lead wire to connect the electronic functional element and the power supply to each other. This makes it possible to easily connect the electronic functional element and the power supply to each other. The external device that can be electrically connected to the electronic functional element is not limited to the power supply, and a signal generator, a transmission device, a reception device, a detection device, a measurement device, a display device, an input device, and the like can also be used.

The present preferred embodiment is able to provide the electronic functional member having electric and electronic functions and excellent stretchability and durability. The electrical connection between the external device such as the power supply and the electronic functional element can be provided by the metal wire of the core wire assembly, such that the external device and the electronic functional element are able to be easily connected to each other.

### Preferred Embodiment 2

An electronic functional member according to the present preferred embodiment has a structure similar to that of the electronic functional member of the preferred embodiment 1 except that a sheath includes a first cover including a knitted fabric and brought into contact with a core wire assembly, and a second cover covering at least a portion of the first cover, and pressing the first cover toward the core wire assembly.

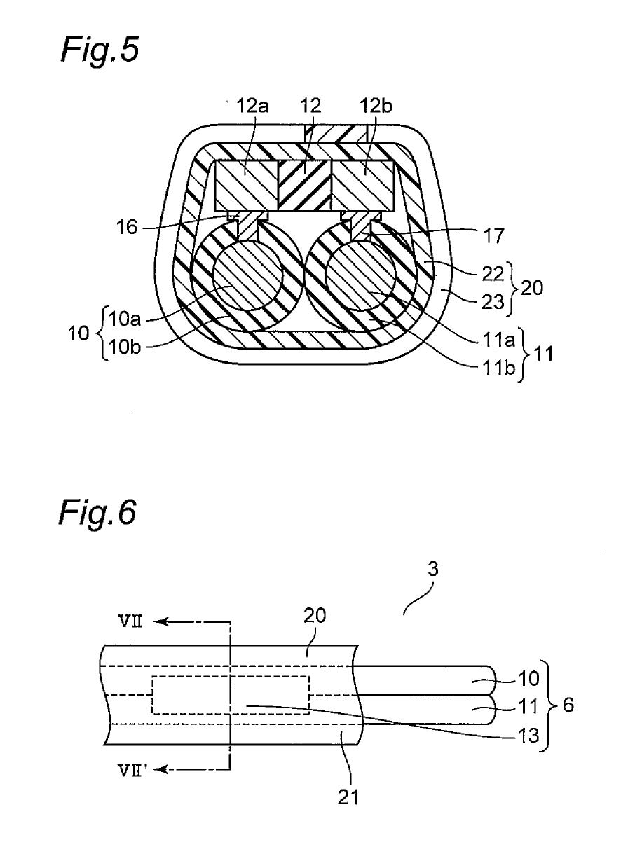

FIG. 4 is a partially broken plan view of the electronic functional member according to the present preferred embodiment, and FIG. 5 is a longitudinal cross-sectional view taken along line V-V′ of FIG. 4. Hereinafter, descriptions of portions common to those of the preferred embodiment 1 will be omitted, and only different portions will be described.

An electronic functional member 2 includes a core wire assembly 5 and a sheath 20 covering the core wire assembly 5. The sheath 20 further includes a first cover 22 including a knitted fabric and located on the side of the core wire assembly 5 and a second cover 23 wound around the first cover 22. The second cover 23 is able to press the first cover 22 toward the core wire assembly 5 to bring the first cover 22 into closer contact with the core wire assembly 5.

For the second cover, an elongated member can be used. Examples of the elongated member include synthetic fiber yarns such as cotton, hemp, and hair, semisynthetic fiber yarns such as cellulose, and synthetic fiber yarns such as nylon, acrylic, polyester, and polyurethane, as well as a composite yarn obtained by combining a plurality of fiber materials, a tape, and a cord. The use of the elongated member makes it possible to bring the first cover into close contact with the core wire assembly without damaging the core wire assembly. When a synthetic fiber yarn containing a thermoplastic resin is used for the first cover, a synthetic fiber yarn containing a thermoplastic resin can also be used for the second cover. After the first cover is coated with the second cover, the synthetic fiber yarn is heated and melted, such that the adhesion of the first cover to the core wire assembly is able to be further improved after cooling.

The electronic functional member according to the present preferred embodiment can be manufactured by using a manufacturing method including a step of helically winding the elongated member around the first cover after forming the first cover. By using a known sheath yarn winding device described in, for example, Japanese Patent Application Laid-open No. Sho 63-282304, the second cover can be formed by unreeling a string wound around a bobbin by rotating the bobbin while moving the electronic functional member including the first cover formed in an upward direction or a downward direction to wind the string around the electronic functional member. The winding interval of the second cover in the longitudinal direction of the electronic functional member can be adjusted as necessary. By decreasing the winding interval (or by increasing the winding number), the adhesion of the first cover to the core wire assembly can be further improved. By increasing the diameter of the yarn of the second cover, the winding interval is able to be decreased to further improve the adhesion of the first cover to the core wire assembly.

The present preferred embodiment makes it possible to provide the second cover to further improve the adhesion of the first cover to the core wire assembly in addition to the effects of the first preferred embodiment.

In the present preferred embodiment, an example in which the second cover is provided is shown, but a cover can also be further provided as necessary. For example, a third cover may be provided as follows. The second cover is spirally wound in the longitudinal direction of the electronic functional member while the third cover is wound in a direction opposite to the second cover on the second cover, and crosses the second cover. By providing the third cover, the adhesion of the first cover to the core wire assembly is able to be further improved.

### Preferred Embodiment 3

An electronic functional member according to the present preferred embodiment has a structure similar to that of the electronic functional member of the preferred embodiment 1 except that an electronic functional substance-containing film is used in place of a chip component as an electronic functional element.

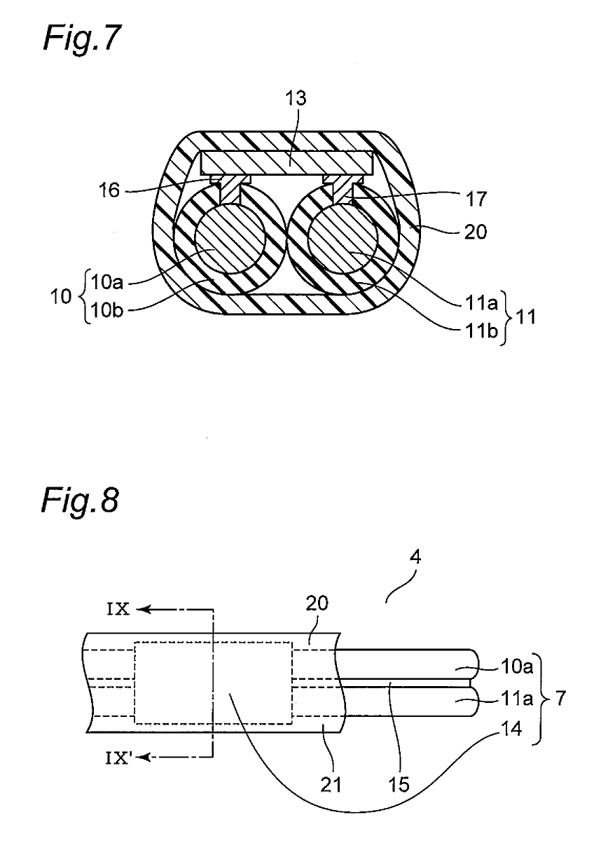

FIG. 6 is a partially broken plan view of an electronic functional member according to the present preferred embodiment, and FIG. 7 is a longitudinal sectional view taken along line VII-VII′ of FIG. 6. Hereinafter, descriptions of portions common to those of the preferred embodiment 1 will be omitted, and only different portions will be described.

An electronic functional member 3 includes a core wire assembly 6 and a sheath 20 covering the core wire assembly 6. The core wire assembly 6 includes a first insulating coating metal wire 10, a second insulating coating metal wire 11, and an electronic functional element 13 including an electronic functional substance-containing film disposed so as to be electrically conductive to each of the first insulating coating metal wire 10 and the second insulating coating metal wire 11.

As described above, the electronic functional substance-containing film can be formed by applying a solution containing an element raw material, for example, a dielectric raw material, to the surfaces of a plurality of metal wires using a known printing method such as spin coating, and heating the solution. A patterned thin film can also be used. Here, examples of the electronic functional substance include a dielectric material, a conductive material, a magnetic material, a piezoelectric material, a semiconductor material, and a pyroelectric material.

According to the present preferred embodiment, in addition to the effects of the preferred embodiment 1, the size and thickness of the electronic functional element mounted on the metal wire is able to be flexibly changed by using the electronic functional substance-containing film, such that the electronic functional member is able to be optimally designed according to the application.

### Preferred Embodiment 4

An electronic functional member according to the present preferred embodiment has a structure similar to that of the preferred embodiment 1 except that an elongated insulating member is used as an insulating layer covering a metal wire, and an electronic functional substance-containing film that covers the plurality of metal wires in strips is used in place of a chip component as an electronic functional element.

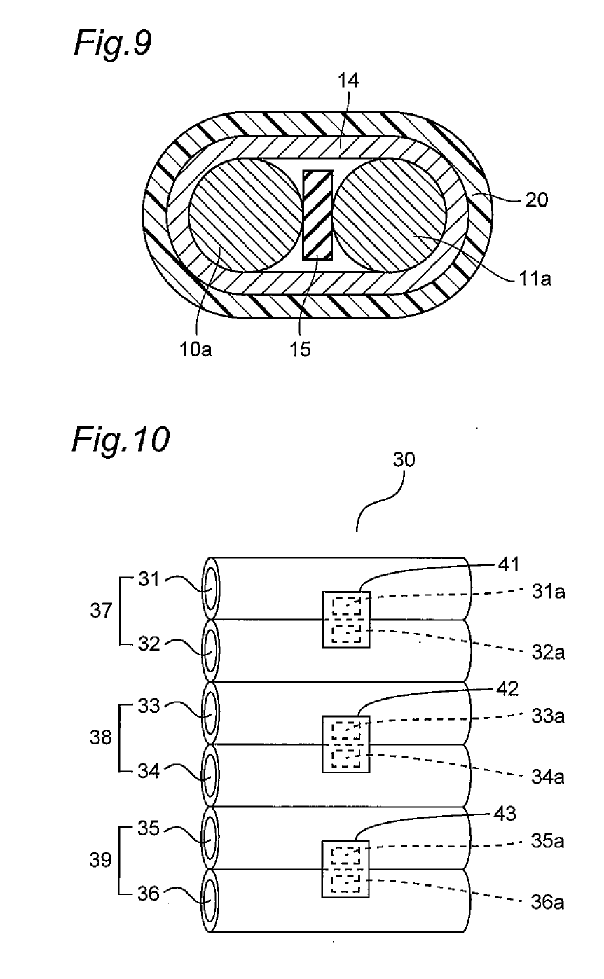

FIG. 8 is a partially broken plan view of an electronic functional member according to the present preferred embodiment, and FIG. 9 is a longitudinal cross-sectional view taken along line IX-IX′ of FIG. 8. An electronic functional member 4 includes a core wire assembly 7 and a sheath 20 covering the core wire assembly 7. The core wire assembly 7 includes metal wires 10a and 11a extending in a longitudinal direction via an insulating member 15, and an electronic functional substance-containing film 14 that covers the metal wires 10a and 11a in stripes and disposed so as to be electrically conductive to the metal wires 10a and 11a. For the sheath 20, a knitted fabric 21 is used, for example.

Examples of the insulating member used in the present preferred embodiment include an elongated insulating sheet interposed between the metal wires, an insulating tape stuck along the longitudinal direction of the metal wire, and an insulating layer extending along the longitudinal direction of the metal wire. As the insulating layer, a polyurethane resin and an acrylic resin, or the like can be used.

As described above, the electronic functional substance-containing film is able to be formed by applying a solution containing an element raw material, for example, a dielectric raw material, to the surfaces of a plurality of metal wires using a known printing method such as spin coating, and heating the solution. A patterned thin film element can also be used.

According to the present preferred embodiment, in addition to the effects of the preferred embodiment 1, the size and thickness of the electronic functional element mounted on the metal wire are able to be flexibly changed by using the electronic functional substance-containing film, such that the electronic functional member is able to be optimally designed according to the application.

In the preferred embodiments 1 to 4, examples in which one electronic functional element is provided are described. However, the electronic functional member of various preferred embodiments of the present invention may include a plurality of electronic functional elements. For example, the electronic functional member may include a first electronic functional element disposed so as to be electrically conductive to each of metal wires of a first wiring including at least two metal wires, and a second electronic functional element being different from the first wiring, and disposed so as to be electrically conductive to each of metal wires of a second wiring including at least two metal wires. In the same manner, the electronic functional member may include a third wiring and a third electronic functional element, a fourth wiring and a fourth electronic functional element, and a fifth wiring and a fifth electronic functional element, and the like. The first electronic functional element and the other electronic functional element may be different from each other, or all the electronic functional elements may be the same. For example, a temperature sensor element (for example, NTC thermistor) can be used for the first electronic functional element and a heating element (for example, PTC thermistor) can be used for the second electronic functional element.

FIG. 10 is a schematic view showing one example of the structure of the above-described electronic functional member including a plurality of electronic functional elements, and the sheath is omitted. A core wire assembly 30 includes metal wires 31, 32, 33, 34, 35, 36 each covered with an insulating layer. The two metal wires 31, 32 define a first wiring 37, the two metal wires 33, 34 define a second wiring 38, and the two metal wires 35, 36 define a third wiring 39. A first electronic functional element 41 is joined to a joint 31a in which a portion of the metal wire 31 is exposed and a joint 32a where a portion of the metal wire 32 is exposed. A second electronic functional element 42 is joined to a joint 33a in which a portion of the metal wire 33 is exposed and a joint 34a in which a portion of the metal wire 34 is exposed. A third electronic functional element 43 is joined to a joint 35a in which a portion of the metal wire 35 is exposed and a joint 36a in which a portion of the metal wire 36 is exposed. FIG. 10 shows an example in which six metal wires are disposed in parallel or substantially in parallel, for example, and the first to third electronic functional elements can also be bundled so as not to bring the first to third electronic functional elements into contact with each other.

In electronic functional members of preferred embodiments of the present invention, the plurality of electronic functional elements may be interconnected by at least two metal wires to define a circuit. This aspect will be described in further detail in the following preferred embodiment 5.

### Preferred Embodiment 5

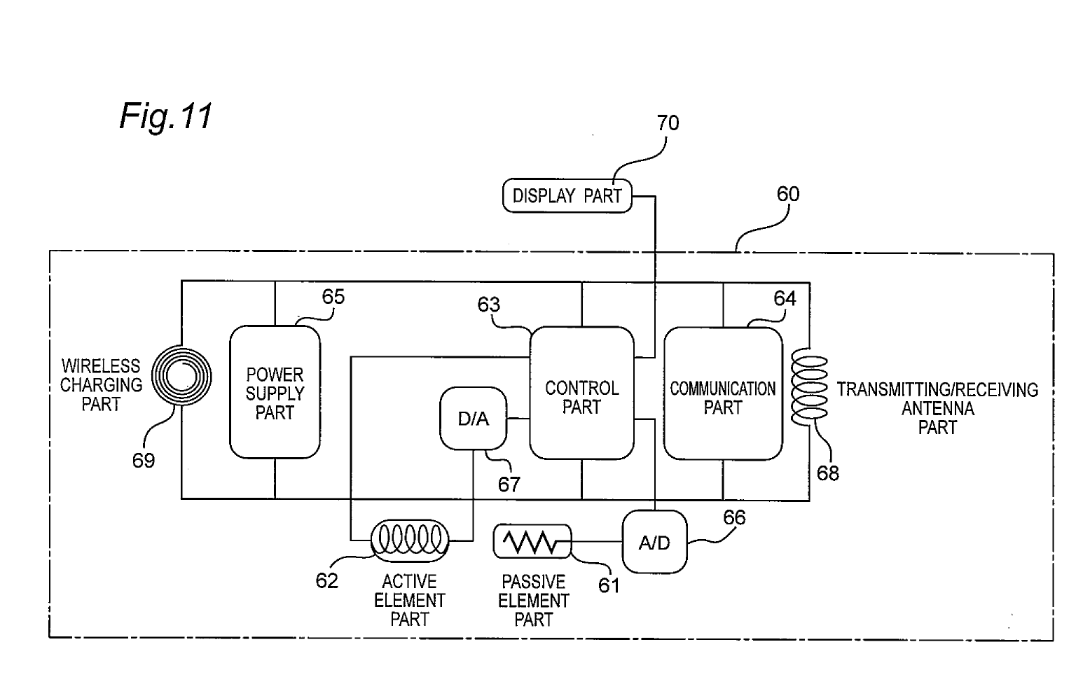

In an electronic functional member according to the present preferred embodiment, a core wire assembly includes a plurality of electronic functional elements, and the plurality of electronic functional elements are interconnected by at least two metal wires to define a circuit (hereinafter, the circuit is also referred to as a built-in circuit). FIG. 11 is a block diagram showing an example of the built-in circuit. A circuit 60 includes a plurality of circuit elements defining a circuit, and the circuit element corresponds to the electronic functional element. The circuit 60 includes, as circuit elements, a passive element 61, an active element 62, a controller 63 configured or programmed to control the operations of the passive element 61 and active element 62, a communicator 64 to output and input a communication signal, a power supply 65 to supply electric power to each of the elements, an A/D converter 66 to A/D convert a data signal from the passive element 61 and output the data signal to the controller 63, a D/A converter 67 to D/A convert a control signal from the controller and supply the control signal to the active element 62, a transmitting/receiving antenna 68 to perform radio transmission/reception with the outside, and a wireless charger 69 to receive radio waves for electric power from the outside and output electric power generated from the radio wave for electric power to the power supply 65. As an external device, a display 70 to display predetermined image information from the controller 63 is provided.

For example, a sensor can be used in the passive element 61. In this case, the passive element is also referred to as a sensor. Examples of the sensor include a temperature sensor, an infrared sensor, a humidity sensor, a sound sensor, an optical sensor, a magnetic sensor, a pressure sensor, an acceleration sensor, and a position sensor. For the active element 62, for example, a heating element or a vibrating body can be used. The combination of the passive element with the active element can be variously selected according to the application of the electronic functional member. For example, by using a temperature sensor as a passive element and using a heating element as an active element, a temperature adjusting function is able to be included in the electronic functional member. For the power supply 65, for example, a capacitor or a secondary battery can be used.

The plurality of electronic functional elements can be interconnected by disposing a plurality of electronic functional elements along the longitudinal direction of two metal wires and making each of the electronic functional elements electrically conductive to each of the metal wires.

The electronic functional member according to the present preferred embodiment can also be formed into a knitted fabric by using a method similar to that described in the preferred embodiment 1. That is, a knitted fabric can be manufactured by supplying an electronic functional member including a built-in circuit to a knitting machine and knitting the electronic functional member as an ordinary thread.

According to the present preferred embodiment, in addition to the advantageous effects of the preferred embodiment 1, the electronic functional member is able to be further downsized by using a circuit in place of a plurality of components such as chips. Furthermore, the shape of a knitted fabric knitted by partially using at least an electronic functional member including a circuit including a sensor is not limited to the shape of an object to be measured, and the knitted fabric is able to be attached to the object to be measured, such that the knitted fabric can be used as a new measuring tool.

In the present preferred embodiment, in the passive element and the circuit element other than the active element, an external device can be used instead of being incorporated in the electronic functional member. In that case, the external device is held by the knitted fabric, but the passive element, the circuit element other than the active element, and the external device can be electrically connected by the metal wire constituting the core wire assembly, as described in the preferred embodiment 1.

The circuit element shown in FIG. 11 is an example, and various circuit elements can be used depending on the application.

The preferred embodiments of the present invention are described above, and those skilled in the art can understand that the preferred embodiments are illustrative, and various modifications are possible within the scope of the present invention. For example, in the preferred embodiment 2, the example is shown, in which the knitting yarn is spirally wound around the first cover as the second cover, but the second cover may be formed by using the knitted fabric. The second cover may be formed by using plating knitting.

Preferred embodiments of the present invention make it possible to provide a novel knitted product such as a clothing article having electronic and electric functions.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic functional member comprising:
a core wire assembly including at least two metal wires, an insulating layer covering the at least two metal wires so as to expose a portion of the at least two metal wires, and an electronic functional element electrically conductive to each of the at least two metal wires; and
a sheath including a knitted fabric covering the core wire assembly.

2. The electronic functional member according to claim 1, wherein the knitted fabric at least partially includes a thermoplastic synthetic resin.

3. The electronic functional member according to claim 1, wherein the core wire assembly is hermetically sealed to an outside in a region where the core wire assembly is covered with the knitted fabric.

4. The electronic functional member according to claim 2, wherein the core wire assembly is hermetically sealed to an outside in a region where the core wire assembly is covered with the knitted fabric.

5. The electronic functional member according to claim 1, wherein the sheath includes a first cover located on a side of the core wire assembly including the knitted fabric, and a second cover covering at least a portion of the first cover and pressing the first cover toward the core wire assembly.

6. The electronic functional member according to claim 5, wherein the second cover is an elongated member helically wound around the first cover.

7. The electronic functional member according to claim 1, wherein the electronic functional element includes at least one of a chip component, an electronic functional substance-containing film, a battery, an input element, a display element, a sensor, an antenna, and a composite element and integrated circuit thereof.

8. The electronic functional member according to claim 1, wherein the core wire assembly includes a plurality of the electronic functional elements interconnected by the at least two metal wires to define a circuit.

9. The electronic functional member according to claim 8, wherein the circuit includes a sensor defining the electronic functional element.

10. The electronic functional member according to claim 9, wherein the circuit further includes a controller that controls operation of the sensor, a communicator that outputs information from the sensor, and a power supply that supplies electric power to the sensor, the controller, and the communicator, as the electronic functional element.

11. The electronic functional member according to claim 1, wherein the sheath directly contacts the electronic functional element.

12. The electronic functional member according to claim 1, wherein the knitted fabric is a weft knitted fabric.

13. A knitted product obtained by knitting the electronic functional member according to claim 1 defining at least a portion of the knitted product.

14. The knitted product according to claim 13, further comprising a power supply electrically connected to the electronic functional element via the at least two metal wires.

15. The knitted product according to claim 13, wherein the knitted product is obtained by knitting the electronic functional member defining at least a portion of the knitted product, the electronic functional member including a circuit in which a sensor, a controller that controls operation of the sensor, a communicator that outputs information from the sensor to an outside, and a power supply that supplies electric power to the sensor, the controller, and the communicator are interconnected by the at least two metal wires.

16. A method for manufacturing an electronic functional member, the method comprising:
forming a core wire assembly including at least two metal wires, an insulating layer covering the at least two metal wires so as to expose a portion of the at least two metal wires, and an electronic functional element electrically conductive to each of the at least two metal wires; and
forming a sheath covering the core wire assembly; wherein
the forming the sheath includes at least knitting a knit fabric by weft knitting around the core wire assembly to cover the core wire assembly.

17. The method according to claim 16, wherein the step of forming the sheath includes a step of helically winding an elongated member around the knitted fabric.

18. The method according to claim 16, wherein the sheath directly contacts the electronic functional element.
